(19) United States
(12) Patent Application Publication
(10) Pub. No.: US 2024/0360634 A1
(43) Pub. Date: Oct. 31, 2024

(54) WALKWAY STRUCTURE AND OVERHEAD HOIST TRANSFER SYSTEM INCLUDING THE SAME

(71) Applicant: SEMES CO., LTD., Cheonan-si (KR)

(72) Inventor: Hyuksoon Im, Pyeongtaek-si (KR)

(21) Appl. No.: 18/643,124

(22) Filed: Apr. 23, 2024

(30) Foreign Application Priority Data
Apr. 28, 2023 (KR) 10-2023-0056592

(51) Int. Cl. E01D 19/10; B66F 11/04

(52) U.S. Cl. CPC E01D 19/106; B66F 11/044

(57) ABSTRACT

A walkway structure includes a first frame spaced apart from the ground in a vertical direction and extending in a first horizontal direction, a footboard located on a side surface of the first frame and comprising at least one first hole, at least one bracket coupled to the footboard and the first frame, and a first coupler configured to couple the bracket to the first frame, wherein the bracket includes a first plate coupled to the footboard, a second plate coupled to the first plate, and a third plate coupled to the second plate, wherein a lower surface of the third plate is in contact with an upper surface of the first frame.

### CROSS-REFERENCE TO RELATED APPLICATION

This application is based on and claims priority under 35 U.S.C. § 119 to Korean Patent Application No. 10-2023-0056592, filed on Apr. 28, 2023, in the Korean Intellectual Property Office, the disclosure of which is incorporated by reference herein in its entirety.

### BACKGROUND

### 1. Field

The disclosure relates to a walkway structure and an overhead hoist transfer system including the same.

### 2. Description of the Related Art

Conveyed objects, such as wafers, glass substrates, printed circuit boards, semiconductor devices, and display devices, may be transferred through unmanned transport systems such as overhead hoist transfer (OHT) apparatuses during processes of manufacturing semiconductor devices or display devices. An OHT apparatus may include transfer vehicles configured to be movable along travel rails installed on the ceiling of clean rooms to transfer conveyed objects.

When issues occur in the OHT apparatus or when repair, maintenance, or the like is needed, walkway structures on which persons may step are needed for work on the ceiling of the clean rooms.

### SUMMARY

Provided are a walkway structure that is easy to install and improves the stability and quickness of work and an overhead hoist transfer system including the same.

In addition, problems to be solved by the spirit of the disclosure are not limited to the above-mentioned problems, and other problems may be clearly understood by one of ordinary skill in the art from the following description.

Additional aspects will be set forth in part in the description which follows and, in part, will be apparent from the description, or may be learned by practice of the presented embodiments of the disclosure.

According to an aspect of the disclosure, a walkway structure includes a first frame spaced apart from the ground in a vertical direction and extending in a first horizontal direction, a footboard located on a side surface of the first frame and including at least one first hole, at least one bracket coupled to the footboard and the first frame, and a first coupler configured to couple the bracket to the first frame, wherein the bracket includes a first plate coupled to the footboard, a second plate coupled to the first plate, and a third plate coupled to the second plate, wherein a lower surface of the third plate is in contact with an upper surface of the first frame.

The first coupler may include a knob bolt.

The second plate may include a hole formed in a center thereof.

The footboard may further include a second hole extending in the vertical direction in an area overlapping the first plate, and the footboard and the bracket may be coupled to each other by a second coupler passing through the second hole.

A horizontal cross-section of the second hole may have a shape extending in a second horizontal direction.

The footboard may further include a plurality of third holes extending in the vertical direction.

The footboard may include a first sidewall formed on one side surface that is not adjacent to the first frame.

The first plate may be coupled to a lower surface of the footboard, the second plate may extend in the vertical direction, and the third plate may extend in a horizontal direction toward the first frame.

The first hole may have a width in a range of about 45 mm to about 55 mm in the first horizontal direction and have a length in a range of about 90 mm to about 110 mm in the second horizontal direction that forms an angle of 90 degrees with the first horizontal direction.

According to another aspect of the disclosure, an overhead hoist transfer system includes a pair of first frames located apart from the ground in a vertical direction and extending in a first horizontal direction, a footboard located between the pair of first frames and including at least one first hole, at least one bracket coupled to any one of the first frames and the footboard, a first coupler configured to couple the bracket to the first frame, at least one pair of travel rails located underneath the first frame and supported by the first frame, and an overhead hoist transfer apparatus moving along the travel rails, wherein the bracket includes a first plate coupled to the footboard, a second plate coupled to the first plate, and a third plate coupled to the second plate, wherein a lower surface of the third plate is in contact with an upper surface of the first frame.

The first plate may be coupled to a lower surface of the footboard, the second plate may extend in the vertical direction, and the third plate may extend in a horizontal direction toward the first frame.

The overhead hoist transfer system may further include a second frame located underneath the first frame and arranged to intersect with the first frame in the vertical direction, wherein the second frame is coupled to the travel rails.

The footboard may further include a second hole extending in the vertical direction in an area overlapping the first plate, and the footboard and the bracket may be coupled to each other by a second coupler passing through the second hole.

The first coupler may include a knob bolt.

The first hole may have a width in a range of about 45 mm to about 55 mm in the first horizontal direction and have a length in a range of about 90 mm to about 110 mm in the second horizontal direction that forms an angle of 90 degrees with the first horizontal direction.

The overhead hoist transfer system may further include a storage box installed adjacent to the travel rail, wherein the storage box includes a plurality of slots.

The storage box may be formed only in an installation area that is a partial area of the travel rail.

According to another aspect of the disclosure, an overhead hoist transfer system includes a pair of first frames located apart from the ground in a vertical direction and extending in a first horizontal direction, a footboard located between the pair of first frames and including at least one first hole, at least one bracket coupled to any one of the first frames and the footboard, a first coupler configured to couple the bracket to the first frame, at least one pair of travel rails located underneath the first frame and supported by the first frame, and an overhead hoist transfer apparatus moving along the travel rails, wherein the bracket includes a first plate coupled to the footboard, a second plate coupled to the first plate, and a third plate coupled to the second plate, wherein a lower surface of the third plate is in contact with an upper surface of the first frame, the first coupler includes a knob bolt, the footboard further includes a second hole extending in the vertical direction in an area overlapping the first plate, the first plate is coupled to a lower surface of the footboard, the second plate extends in the vertical direction, the third plate extends in a horizontal direction toward the first frame, and the footboard and the bracket are coupled to each other by a second coupler passing through the second hole.

The first hole may have a width in a range of about 45 mm to about 55 mm in the first horizontal direction and have a length in a range of about 90 mm to about 110 mm in the second horizontal direction that forms an angle of 90 degrees with the first horizontal direction.

The overhead hoist transfer system may further include a storage box installed adjacent to the travel rail, wherein the storage box includes a plurality of slots, and the storage box is formed only in an installation area that is a partial area of the travel rail.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a perspective view schematically illustrating a walkway structure according to an embodiment;

FIG. 2 is an enlarged view of a portion AA of the walkway structure of FIG. 1;

FIG. 3 is a plan view schematically illustrating a shape in which the walkway structure of FIG. 1 is coupled to a first frame;

FIG. 4 is a cross-sectional view taken along line X-X′ of FIG. 3;

FIG. 5 is a side view schematically illustrating an overhead hoist transfer system according to embodiments;

FIGS. 6 and 7 are perspective views schematically illustrating a storage box for a walkway structure, according to embodiments; and

FIG. 8 is a plan view schematically illustrating an overhead hoist transfer system according to embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, embodiments will be described in detail with reference to the accompanying drawings. The same reference numerals are used for the same components in the drawings, and the same descriptions thereof are omitted.

In embodiments, when one element is referred to as being disposed on or connected or coupled to the other element, the element may be directly disposed on or connected or coupled to the other element, or intervening elements may be present. Alternatively, when one element is referred to as being directly disposed on or connected or coupled to the other element, intervening elements may not be present. Although the terms first, second, third etc. may be used herein to describe various elements, components, regions, layers and/or sections, these elements, components, regions, layers and/or sections should not be limited by these terms.

The technical terms used in the embodiments are used only for the purpose of describing particular embodiments and are not intended to limit the disclosure. Unless otherwise defined, all terms (including technical and scientific terms) used herein have the same meaning as commonly understood by one of ordinary skill in the art to which embodiments belong. Terms, such as those defined in commonly used dictionaries, should be interpreted as having a meaning that is consistent with their meaning in the context of the relevant art and will not be interpreted in an idealized or overly formal sense unless expressly so defined herein.

Embodiments are described with reference to the schematic drawings of the embodiments. As such, variations from the shapes of the illustrations as a result, for example, of manufacturing techniques and/or tolerances, are to be expected. Thus, embodiments should not be construed as limited to the particular shapes of regions illustrated herein but may be to include deviations in shapes that result, for example, from manufacturing. The elements depicted in the drawings are purely schematic and their shapes are not intended to illustrate the exact shapes of the elements nor are they intended to limit the scope of the disclosure.

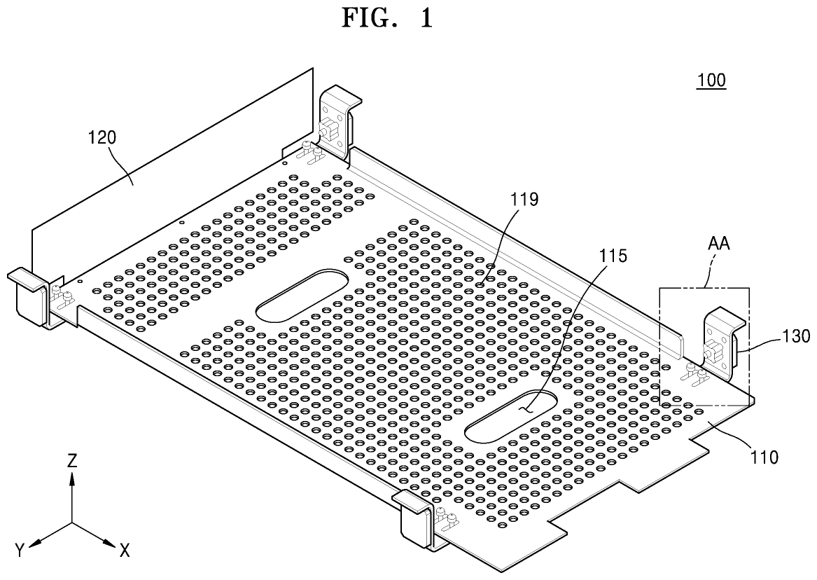

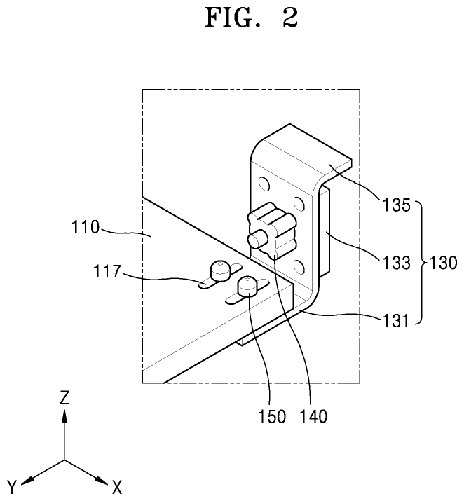

FIG. 1 is a perspective view schematically illustrating a walkway structure according to an embodiment. FIG. 2 is an enlarged view of a portion AA of the walkway structure of FIG. 1.

Referring to FIGS. 1 and 2, a walkway structure 100 may include a footboard 110, a bracket 130, and a first sidewall 120. The footboard 110 may have a flat plate shape so that a worker may step thereon. According to embodiments, the footboard 110 may be a flat plate having a rectangular horizontal cross-section, but is not limited thereto.

The footboard 110 may include a first hole 115, a second hole 117, and a third hole 119. The first hole 115 may be formed to enable the worker to grip the footboard 110 to install the walkway structure 100. According to embodiments, the first hole 115 may be formed in a central portion of the footboard 110. A plurality of first holes 115 may be provided to be spaced apart from each other in a horizontal direction. According to embodiments, the first hole 115 may have an elliptical shape, but is not limited thereto.

According to embodiments, the first hole 115 may have a width in a range of 45 mm to 55 mm in a first horizontal direction X and have a length in a range of 90 mm to 110 mm in a second horizontal direction Y. When the first hole 115 has the above range, the worker may easily grip the footboard 110 and move the footboard 110 or couple the footboard 110 to another structure.

The second hole 117 may be formed in the footboard 110 to be adjacent to the bracket 130. The second hole 117 may pass through the footboard 110 in a vertical direction Z, but may have a shape extending in the second horizontal direction Y. In other words, the second hole 117 may have a shape that moves away from the bracket 130 in the second horizontal direction Y. A horizontal cross-section of the second hole 117 may have an elliptical or rectangular shape extending in the second horizontal direction Y.

The third holes 119 may pass through the footboard 110 in the vertical direction Z, and a plurality of third holes 119 may be provided. The plurality of third holes 119 may be formed over the entire footboard 110. When the plurality of third holes 119 are formed, a weight of the footboard 110 may be reduced, and thus, an overall weight of the walkway structure 100 may be reduced.

The bracket 130 may be located on a side of the footboard 110 in the second horizontal direction Y. A plurality of brackets 130 may be provided, and each of the plurality of brackets 130 may be located on the side of the footboard 110 in the second horizontal direction Y. The bracket 130 may be coupled to the footboard 110 through a second coupler 150. Here, according to embodiments, the second coupler 150 may be coupled to the bracket 130 through the second hole 117 formed in the footboard 110.

According to embodiments, the bracket 130 may include a first plate 131, a second plate 133, and a third plate 135. The first plate 131 may have a shape extending in the second horizontal direction Y and may be coupled to the footboard 110. The second plate 133 may have a shape extending in the vertical direction Z and may be coupled to the first plate 131 or integrally formed with the first plate 131. The third plate 135 may have a shape extending in the second horizontal direction Y and may be coupled to the second plate 133 or integrally formed with the second plate 133.

According to embodiments, the first plate 131 may be located on a lower surface of the footboard 110 and may include a hole formed in a central portion of the first plate 131. The second coupler 150 may couple the footboard 110 to the first plate 131 by simultaneously passing through the hole of the first plate 131 and the second hole 117 of the footboard 110. In some embodiments, the second coupler 150 may include a bolt and a nut.

When the second coupler 150 couples the footboard 110 to the bracket 130 by passing through the second hole 117 of the footboard 110 and the hole of the first plate 131, the second hole 117 of the footboard 110 may have a shape extending in the second horizontal direction Y, and thus, the second coupler 150 may have a degree of freedom in the second horizontal direction Y. In other words, the second coupler 150 may move in the second horizontal direction Y along the second hole 117. Accordingly, the first plate 131 may also be moved in the second horizontal direction Y by the movement of the second coupler 150.

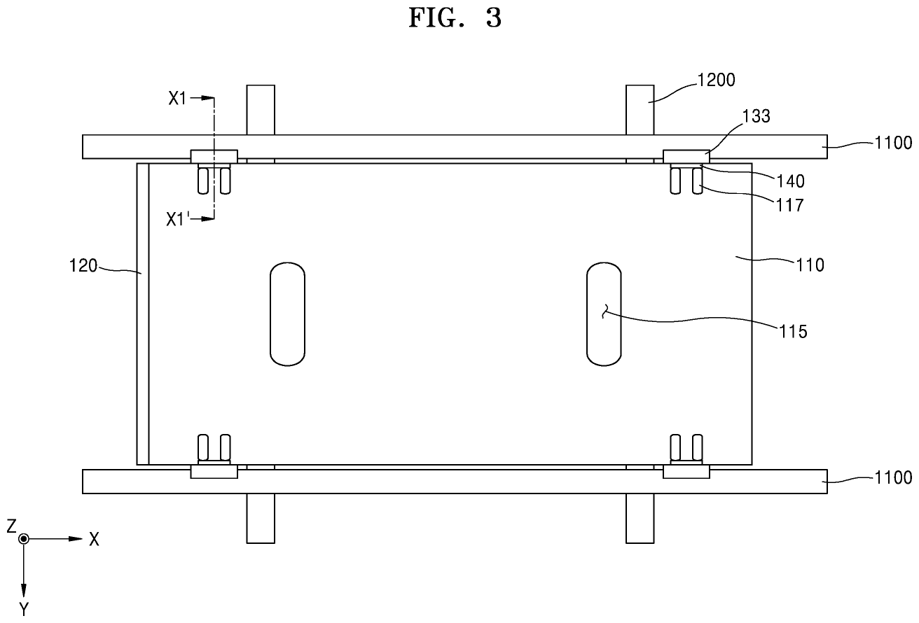

Therefore, the first plate 131 may move a certain distance in the second horizontal direction Y, and thus, as described below, when the bracket 130 is coupled to a first frame 1100 (refer to FIG. 3), an error may occur between the bracket 130 and the first frame 1100 in the second horizontal direction Y. Here, the error may be solved and the bracket 130 may be easily coupled to the first frame 1100 by moving the first plate 131 in the second horizontal direction Y.

The second plate 133 may be coupled to an upper surface of the first plate 131 and may extend in the vertical direction Z. A hole extending in the second horizontal direction Y may be formed in a central portion of the second plate 133.

The third plate 135 may be coupled to an upper surface of the second plate 133 and may have a shape extending in the second horizontal direction Y.

The first sidewall 120 may be formed on a side of the footboard 110 in the first horizontal direction X. According to embodiments, the first sidewall 120 may be formed only on one side surface of the footboard 110 in the first horizontal direction X, but is not limited thereto, and the first sidewall 120 may be formed on both side surfaces of the footboard 110 in the first horizontal direction X.

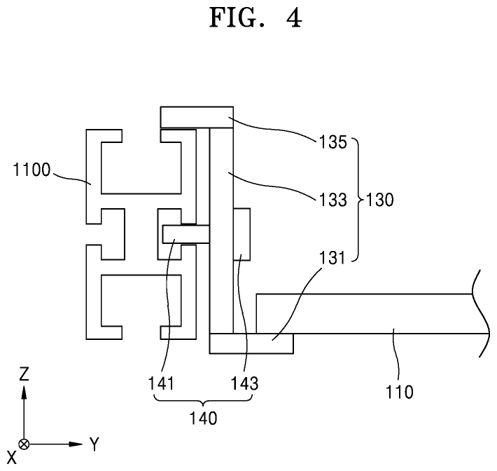

FIG. 3 is a plan view schematically illustrating a shape in which the walkway structure 100 of FIG. 1 is coupled to a first frame. FIG. 4 is a cross-sectional view taken along line X1-X1′ of FIG. 3.

Referring to FIGS. 3 and 4, the walkway structure 100 may be coupled to the first frame 1100 through a bracket 130. According to embodiments, the walkway structure 100 may be coupled to a pair of first frames 1100 through four brackets 130 in a second horizontal direction Y.

The first frame 1100 may have a shape extending in a first horizontal direction X and may have an H-shaped vertical cross-section as shown in FIG. 4. However, the vertical cross-section of the first frame 1100 is not limited to the above shape, and the first frame 100 may have various cross-sectional shapes. According to embodiments, a plurality of first frames 1100 may be provided and may be spaced apart from each other in parallel in the second horizontal direction Y.

A second frame 1200 may be located underneath the first frame 1100 and may have a shape extending in the second horizontal direction Y. A plurality of second frames 1200 may be provided and may be spaced apart from each other in parallel in the first horizontal direction X.

The first frame 1100 and the second frame 1200 may be spaced apart from the ground in a vertical direction Z. For example, the first frame 1100 and the second frame 1200 may be frames provided on the ceiling of a clean room.

The first frame 1100 may have a hole extending in the second horizontal direction Y. The bracket 130 may be coupled to the first frame 1100 through a first coupler 140. Here, the first coupler 140 may couple the bracket 130 to the first frame 1100 by simultaneously passing through a hole formed in a second plate 133 of the bracket 130 and the hole formed in the first frame 1100.

When the walkway structure 100 is coupled to the first frame 1100, a third plate 135 may overlap the first frame 1100 in the vertical direction Z. Here, the walkway structure 100 may be fixed to the first frame 1100 by the first coupler 140 and may withstand a load through the third plate 135. In other words, when the third plate 135 has a shape extending in the second horizontal direction Y and overlaps an upper surface of the first frame 1100 in the vertical direction Z, the third plate 135 may contact the upper surface of the first frame 1100. Here, a load applied to a footboard 110 may be offset by a normal force between the third plate 135 and the first frame 1100. Accordingly, a load applied when a worker steps on the walkway structure 100 may be supported by the first frame 1100 and the third plate 135.

According to embodiments, the first coupler 140 may include a knob 143 and a T-bolt 141. As used herein, the knob 143 and the T-bolt 141 may be simply referred to as a knob bolt. The first coupler 140 may include the knob bolt, and thus, the worker may easily couple the walkway structure 100 to the first frame 1100. In other words, the first frame 1100 and the second plate 133 may be simply coupled to each other by inserting the T-bolt 141 into a hole of a second plate 133 and the hole of the first frame 1100 and then turning the knob 143.

In the existing art, the first frame 1100 and the walkway structure 100 may be coupled to each other through bolts and nuts. In addition, the walkway structure 100 and the first frame 1100 may be coupled to each other in the vertical direction Z. Accordingly, a lot of time may be taken to install the walkway structure 100, and a lot of time may also be taken for work for releasing the walkway structure 100. However, the walkway structure 100 according to the disclosure may be coupled to the first frame 1100 on a side of the walkway structure 100 and may be coupled to the first frame 1100 through the knob bolt, and thus, the coupling and releasing time may be reduced. In addition, the load applied to the walkway structure 100 may be supported through the third plate 135, and thus, the reliability of the walkway structure 100 may be improved and the stability and quickness of work by the worker may be improved.

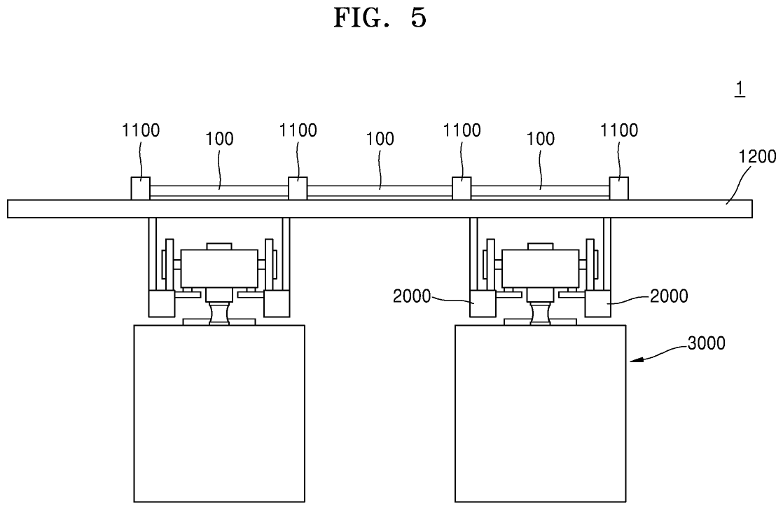

FIG. 5 is a side view schematically illustrating an overhead hoist transfer system according to embodiments.

An overhead hoist transfer system 1 may include a travel rail 2000 and an overhead hoist transfer apparatus 3000.

The travel rail 2000 may be configured to provide a conveyance path for conveying objects between pieces of manufacturing equipment. The overhead hoist transfer apparatus 3000 may be configured to return a container, which accommodates substrates, along the travel rail 2000 to the pieces of manufacturing equipment for a next manufacturing process. The overhead hoist transfer apparatus 3000 may be configured to store a carrier therein. The carrier may be a carrier that accommodates semiconductor substrates such as wafers. The carrier may include a sealed container to protect the substrates from foreign substances or chemical contamination in the atmosphere.

The carrier may include a body having an open space on one side and a door that opens and closes the body. A plurality of slots into which a portion of an edge of a substrate is inserted may be provided on an inner sidewall of the body. The slots may be provided on the inner sidewall of the body while being spaced apart from one another in a vertical direction Z at certain intervals. The body may have a material and/or structure optimized for extreme cleanliness. A leaf spring may be installed on the inner wall of the door to apply certain pressure to the substrates loaded within the carrier while the door is closed.

The travel rail 2000 may be installed underneath a second frame 1200 formed on the ceiling. The travel rail 2000 and the second frame 1200 may be fixed through a long-term buckle or the like. A first frame 1100 may be located on the second frame 1200, and the first frame 1100 may be formed to intersect with the second frame 1200 in the vertical direction Z.

The first frame 1100 may be coupled to walkway structures 100. Accordingly, a worker may perform work on the travel rail 2000 and the overhead hoist transfer apparatus 3000 through the walkway structures 100.

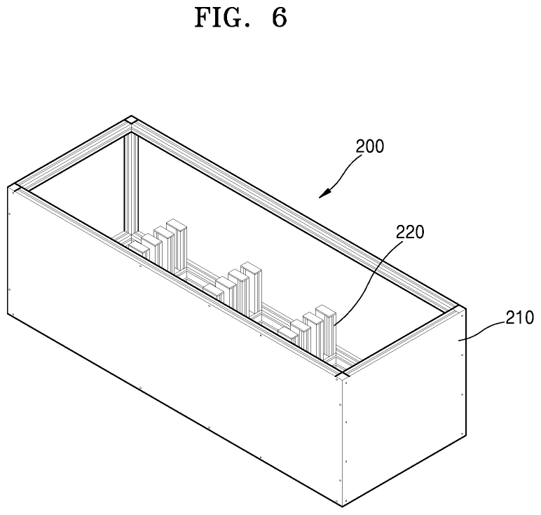

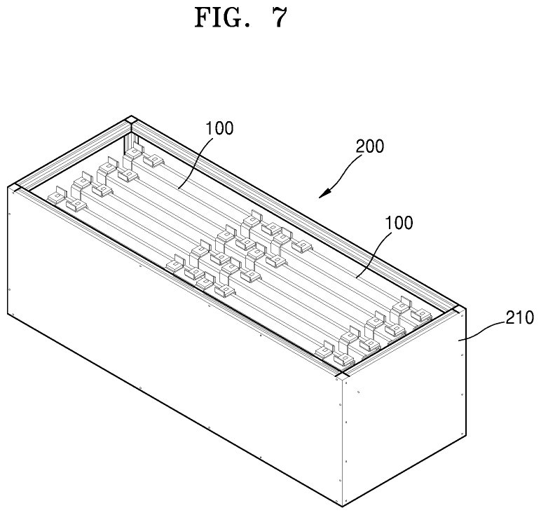

FIGS. 6 and 7 are perspective views schematically illustrating a storage box for a walkway structure, according to embodiments.

Referring to FIGS. 6 and 7, a walkway structure 100 may be loaded through a storage box 200. The storage box 200 may include a body 210 and slots 220. As shown in FIG. 6, a plurality of slots 220 may be spaced apart from one another in parallel in a horizontal direction and may have a shape extending in a vertical direction. Accordingly, as shown in FIG. 7, the walkway structures 100 may be loaded one by one between the plurality of slots 220 within the body 210 of the storage box 200.

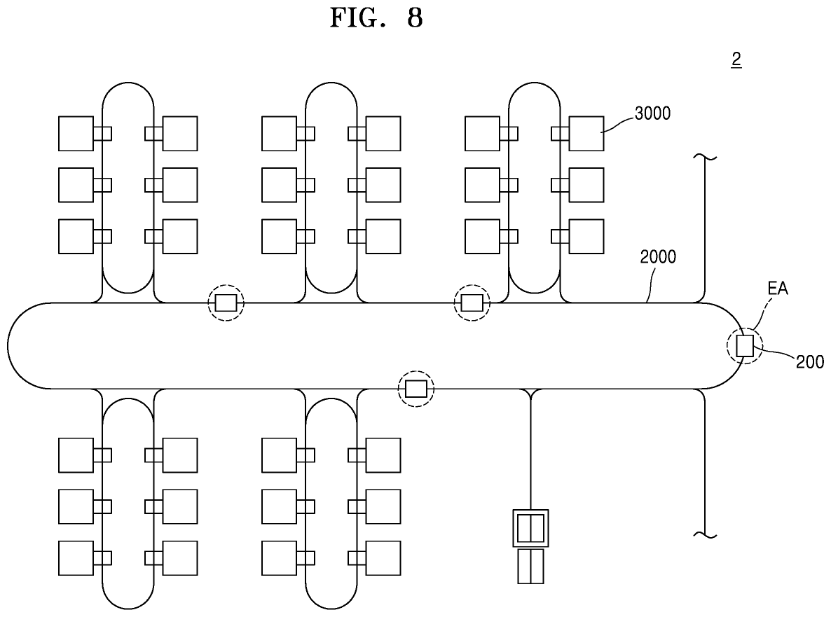

FIG. 8 is a plan view schematically illustrating an overhead hoist transfer system according to embodiments. Hereinafter, the same description of an overhead hoist transfer system 2 of FIG. 8 as the overhead hoist transfer system 1 of FIG. 7 is omitted and differences therebetween are mainly described.

The overhead hoist transfer system 2 may include a plurality of storage boxes 200 disposed on a travel rail 2000. Each of the plurality of storage boxes 200 may be arranged with the walkway structures 100 of FIG. 7 loaded therein.

The storage boxes 200 may be installed in an area in which work by a worker frequently occurs in an existing overhead hoist transfer system. The area may be understood as an installation area EA. The overhead hoist transfer system 2 of the disclosure may be configured such that the walkway structures 100 are not installed over the entire travel rail 2000 but are arranged inside the storage box 200 while loaded in the storage box 200 installed in the installation area EA and then are installed only in a needed area.

Therefore, the walkway structure 100 does not need to be constantly installed, and an effect of the walkway structure 100 on a clean room may be reduced by installing and releasing the walkway structure 100 in a needed area.

Accordingly, an illumination issue caused by formation of the walkway structure 100 over the entire ceiling of the clean room, an issue of an airflow, which flows from the top to the bottom, being scattered by the walkway structure 100 or flowing back to the top, and the like may be solved. In other words, only when needing work, the worker may take the walkway structure 100 out of the storage box 200 and install the walkway structure 100, and thus, light may reach the floor of the clean room and the airflow flowing from the top to the floor of the clean room may also not be disturbed by the walkway structure 100.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A walkway structure comprising:
a first frame located apart from the ground in a vertical direction and extending in a first horizontal direction;
a footboard located on a side surface of the first frame and comprising at least one first hole;
at least one bracket coupled to the footboard and the first frame; and
a first coupler configured to couple the bracket to the first frame, wherein the bracket comprises: a first plate coupled to the footboard; a second plate coupled to the first plate; and a third plate coupled to the second plate, wherein a lower surface of the third plate is in contact with an upper surface of the first frame.

2. The walkway structure of claim 1, wherein the first coupler comprises a knob bolt.

3. The walkway structure of claim 1, wherein the second plate comprises a hole formed in a center thereof.

4. The walkway structure of claim 1, wherein the footboard further comprises a second hole extending in the vertical direction in an area overlapping the first plate, and the footboard and the bracket are coupled to each other by a second coupler passing through the second hole.

5. The walkway structure of claim 4, wherein a horizontal cross-section of the second hole has a shape extending in a second horizontal direction.

6. The walkway structure of claim 1, wherein the footboard further comprises a plurality of third holes extending in the vertical direction.

7. The walkway structure of claim 1, wherein the footboard comprises a first sidewall formed on one side surface that is not adjacent to the first frame.

8. The walkway structure of claim 1, wherein the first plate is coupled to a lower surface of the footboard, the second plate extends in the vertical direction, and the third plate extends in a horizontal direction toward the first frame.

9. The walkway structure of claim 1, wherein the first hole has a width in a range of about 45 mm to about 55 mm in the first horizontal direction and has a length in a range of about 90 mm to about 110 mm in the second horizontal direction that forms an angle of 90 degrees with the first horizontal direction.

10. An overhead hoist transfer system comprising:
a pair of first frames located apart from the ground in a vertical direction and extending in a first horizontal direction;
a footboard located between the pair of first frames and comprising at least one first hole;
at least one bracket coupled to any one of the first frames and the footboard;
a first coupler configured to couple the bracket to the first frame;
at least one pair of travel rails located underneath the first frame and supported by the first frame; and
an overhead hoist transfer apparatus moving along the travel rails, wherein the bracket comprises: a first plate coupled to the footboard; a second plate coupled to the first plate; and a third plate coupled to the second plate, wherein a lower surface of the third plate is in contact with an upper surface of the first frame.

11. The overhead hoist transfer system of claim 10, wherein the first plate is coupled to a lower surface of the footboard, the second plate extends in the vertical direction, and the third plate extends in a horizontal direction toward the first frame.

12. The overhead hoist transfer system of claim 10, further comprising a second frame located underneath the first frame and arranged to intersect the first frame in the vertical direction, wherein the second frame is coupled to the travel rails.

13. The overhead hoist transfer system of claim 10, wherein the footboard further comprises a second hole extending in the vertical direction in an area overlapping the first plate, and the footboard and the bracket are coupled to each other by a second coupler passing through the second hole.

14. The overhead hoist transfer system of claim 10, wherein the first coupler comprises a knob bolt.

15. The overhead hoist transfer system of claim 10, wherein the first hole has a width in a range of about 45 mm to about 55 mm in the first horizontal direction and has a length in a range of about 90 mm to about 110 mm in the second horizontal direction that forms an angle of 90 degrees with the first horizontal direction.

16. The overhead hoist transfer system of claim 10, further comprising a storage box installed adjacent to the travel rail, wherein the storage box comprises a plurality of slots.

17. The overhead hoist transfer system of claim 16, wherein the storage box is formed only in an installation area that is a partial area of the travel rail.

18. An overhead hoist transfer system comprising:
a pair of first frames located apart from the ground in a vertical direction and extending in a first horizontal direction;
a footboard located between the pair of first frames and comprising at least one first hole;
at least one bracket coupled to any one of the first frames and the footboard;
a first coupler configured to couple the bracket to the first frame;
at least one pair of travel rails located underneath the first frame and supported by the first frame; and
an overhead hoist transfer apparatus moving along the travel rails, wherein the bracket comprises: a first plate coupled to the footboard; a second plate coupled to the first plate; and a third plate coupled to the second plate, wherein a lower surface of the third plate is in contact with an upper surface of the first frame, the first coupler comprises a knob bolt, the footboard further comprises a second hole extending in the vertical direction in an area overlapping the first plate, the first plate is coupled to a lower surface of the footboard, the second plate extends in the vertical direction, the third plate extends in a horizontal direction toward the first frame, and the footboard and the bracket are coupled to each other by a second coupler passing through the second hole.

19. The overhead hoist transfer system of claim 18, wherein the first hole has a width in a range of about 45 mm to about 55 mm in the first horizontal direction and has a length in a range of about 90 mm to about 110 mm in the second horizontal direction that forms an angle of 90 degrees with the first horizontal direction.

20. The overhead hoist transfer system of claim 18, further comprising a storage box installed adjacent to the travel rail, wherein the storage box comprises a plurality of slots, and the storage box is formed only in an installation area that is a partial area of the travel rail.
